(19) United States
(12) Patent Application Publication
(10) Pub. No.: US 2021/0382818 A1
(43) Pub. Date: Dec. 9, 2021

(54) Solid-State Storage Devices that Reduce Read Time for Read Time-Sensitive Data

(71) Applicant: Western Digital Technologies, Inc., San Jose, CA (US)

(72) Inventors: Amit Sharma, Bengaluru (IN); Abhinandan Venugopal, Bengaluru (IN); Vijay Chinchole, Bengaluru (IN)

(21) Appl. No.: 16/895,907

(22) Filed: Jun. 8, 2020

(51) Int. Cl. G06F 12/02; G06F 12/0882; G06F 12/1045; G06F 13/16; G11C 16/30; G11C 16/10

(52) U.S. Cl. CPC G06F 12/0246; G06F 12/0253; G06F 12/0882; G06F 12/1045; G06F 2212/7209; G11C 16/30; G11C 16/10; G06F 2212/7201; G06F 2212/7211; G06F 13/1684

(57) ABSTRACT

Disclosed herein is a solid-state storage device that reduces read time for read time-sensitive data (“RTS data”). Data-characterizing logic characterizes incoming data from a host system as primary data including the RTS data or secondary data including non-RTS data. Memory-cell programming schemes include a primary data-programming scheme for a reduced read-frequency zone for the primary data and a secondary data-programming scheme standard read-frequency zone for the secondary data. Data routing logic routes the primary data to a plurality of physical pages corresponding to lower logical pages of a plurality of logical pages in the at-least-one reduced read-frequency zone with assistance by a logical-to-physical address translator. The lower logical pages require fewer read operations than upper logical pages of the plurality of logical pages to read the primary data, which results in a reduction of the read time for the RTS data in the at-least-one reduced read-frequency zone.

### BACKGROUND

Newer solid-state storage devices such as those including triple-level cell (“TLC”) or quad-level cell (“QLC”) NAND-flash packages store more data per memory cell than older solid-state storage devices such as those including single-level cell (“SLC”) or multi-level cell (“MLC”) NAND-flash packages. While this has advantageously driven costs down for manufacturers and consumers alike, such newer solid-state storage devices require an increased number of read operations per memory cell, which disadvantageously increases read time per memory cell. A likelihood of read disturb errors is also increased in the newer solid-state storage devices due the increased number of read operations per memory cell. Efforts to overcome the foregoing disadvantages of the newer solid-state storage devices to date have led to hybrid solid-state storage devices such as those including both SLC and TLC NAND-flash packages, in which read-time sensitive (“RTS”) data or frequently accessed data is placed in SLC-type memory cells to decrease read time for the RTS data, as well as reduce the likelihood of read disturb errors. However, such hybrid solid-state storage devices disadvantageously have lower storage capacities, which is counter to market demand for producing the newer, higher storage-capacity solid-state storage devices. What is needed is a solid-state storage device that overcomes the disadvantages of the newer solid-state storage devices without reducing storage capacity.

Disclosed herein are solid-state storage devices and methods thereof for RTS data that address at least the foregoing.

### SUMMARY

Disclosed herein is a solid-state storage device configured to reduce read time for RTS data. The solid-state storage device includes, in some embodiments, one or more flash packages, a controller, and one or more busses connecting the one-or-more flash packages to the controller. Each flash package of the one-or-more flash packages includes an array of memory cells. The controller includes data-characterizing logic, memory-cell programming schemes, and data routing logic. The data-characterizing logic is configured to characterize incoming data from a host system as primary data including the RTS data, secondary data including non-RTS data, or uncharacterizable data. The memory-cell programming schemes include a primary data-programming scheme and a secondary data-programming scheme. The primary data-programming scheme is for at least one reduced read-frequency zone for the primary data. The secondary data-programming scheme is for at least one standard read-frequency zone for the secondary data, the uncharacterizable data, or a combination thereof. In accordance with a logical-to-physical address translator, the data routing logic is configured for routing the primary data to lower logical pages of a plurality of logical pages in the at-least-one reduced read-frequency zone. The lower logical pages require fewer read operations than upper logical pages of the plurality of logical pages to read the primary data.

In some embodiments, the data-characterizing logic is further configured to characterize the incoming data from the host system as likely to be frequently accessed data or seldomly accessed data. The primary data further includes the likely-to-be frequently accessed data. The secondary data further includes the likely-to-be seldomly accessed data.

In some embodiments, the primary data-programming scheme and the secondary data-programming scheme are implemented within at least one die of the one-or-more flash packages. As such, the at-least-one reduced read-frequency zone and the at-least-one standard read-frequency zone are within the at-least-one die.

In some embodiments, the primary data-programming scheme and the secondary data-programming scheme are implemented between at least two different dies of the one-or-more flash packages. As such, each die of the at-least-two different dies has a different read-frequency zone of the at-least-one reduced read-frequency zone and the at-least-one standard read-frequency zone.

In some embodiments, all blocks of a plurality of blocks in each plane of one or more planes are configured with a same storage capacity.

In some embodiments, each memory cell of the array of memory cells is a triple-level memory cell configured to have an erased state and up to seven programmed states. The erased state and the seven programmed states correspond to a total of eight different amounts of floating gate-trapped electrons with eight different readable threshold voltages for up to three bits of data per memory cell.

In some embodiments, each memory cell of the array of memory cells is a quad-level memory cell configured to have an erased state and up to fifteen programmed states. The erased state and the fifteen programmed states correspond to a total of sixteen different amounts of floating gate-trapped electrons with sixteen different readable threshold voltages for up to four bits of data per memory cell.

In some embodiments, the primary data-programming scheme is configured for programming the array of memory cells in the at-least-one reduced read-frequency zone such that the primary data is represented by lower significant bits of four-bit tuples in the lower logical pages of four logical pages. The lower significant bits require only one or two read operations per memory cell to determine their values.

In some embodiments, the primary data-programming scheme is configured for programming the array of memory cells in the at-least-one reduced read-frequency zone such that the secondary data is represented by upper significant bits of the four-bit tuples in the upper logical pages of the four logical pages. The upper significant bits require four to eight read operations per memory cell to determine their values.

In some embodiments, the primary data-programming scheme is configured for programming the array of memory cells in the at-least-one reduced read-frequency zone such that the primary data is represented by a least significant bit (“LSB”), a lower-middle significant bit (“LMSB”), or both the LSB and the LMSB of four-bit tuples. The LSB of a four-bit tuple is in an LSB logical page of a set of four logical pages and requires only one read operation per memory cell to determine its value. The LMSB of a same or different four-bit tuple is in an LMSB logical page of the set of four logical pages and requires only one or two read operations per memory cell to determine its value.

In some embodiments, the primary data-programming scheme is configured for programming the array of memory cells in the at-least-one reduced read-frequency zone such that the secondary data is represented by an upper-middle significant bit (“UMSB”), a most significant bit (“MSB”), or both the UMSB and the MSB of the four-bit tuples. The UMSB of the same or different four-bit tuple is in a UMSB logical page of the set of four logical pages and requires four or five read operations per memory cell to determine its value. The MSB of the same or different four-bit tuple is in an MSB logical page of the set of four logical pages and requires seven or eight read operations per memory cell to determine its value.

In some embodiments, the secondary data-programming scheme is configured for programming the array of memory cells in the at-least-one standard read-frequency zone such that the secondary data, the uncharacterizable data, or the combination thereof is represented by any combination of the LSB, LMSB, UMSB, or MSB of the four-bit tuples. Each bit of the LSB, LMSB, UMSB, or MSB of the same or different four-bit tuple require three or four read operations per memory cell to determine its value.

In some embodiments, each memory cell of the array of memory cells is a penta-level memory cell configured to have an erased state and up to thirty-one programmed states. The erased state and the thirty-one programmed states correspond to a total of thirty-two different amounts of floating gate-trapped electrons with thirty-two different readable threshold voltages for up to five bits of data per memory cell.

In some embodiments, the controller further includes a garbage collection module and a wear-leveling module. The garbage-collection module is configured to erase erase-designated blocks of a plurality of blocks including invalid logical pages having invalid data. The wear-leveling module is configured to evenly distribute valid data from valid logical pages of the erase-designated blocks in a plurality of memory cell-programming instances over erased blocks of the plurality of blocks in each zone of the at-least-one reduced read-frequency zone and the at-least-one standard read-frequency zone in accordance with any recharacterization of the valid data by the data-characterizing logic.

Also disclosed herein is a data center configured to reduce read time for RTS data. The data center includes a plurality of solid-state storage devices, memory-cell programming schemes, data-characterizing logic, and data-routing logic. Each solid-state storage device of the plurality of solid-state storage devices includes an array of memory cells and a controller including a processor to handle data flow to and from the array of memory cells. The memory-cell programming schemes include a primary data-programming scheme and a secondary data-programming scheme respectively for at least one reduced read-frequency zone and at least one standard read-frequency zone. The primary data-programming scheme and the secondary data-programming scheme are distributed among different rack-units holding the plurality of solid-state storage devices. The data-characterizing logic is configured to characterize incoming data as primary data including the RTS data, secondary data including non-RTS data, or uncharacterizable data. The data-routing logic is configured for routing both the primary data and a portion the secondary data to the solid-state storage devices in the at-least-one reduced read-frequency zone. Lower logical pages including the primary data require fewer read operations than upper logical pages including the secondary data.

Also disclosed is a method implemented by a solid-state storage device configured to reduce read time for RTS data. The method includes an incoming data-characterizing operation, a primary data-routing operation, a first memory cell-programming operation, and a first memory cell-reading operation. The incoming data-characterizing operation includes characterizing incoming data from a host system as primary data including the RTS data, secondary data including non-RTS data, or uncharacterizable data. The incoming data-characterizing operation is performed by data-characterizing logic of a controller of the solid-state storage device. The primary data-routing operation includes routing the primary data in accordance with a logical-to-physical address translator of the controller to lower logical pages of a plurality of logical pages in at least one reduced read-frequency zone of the solid-state storage device. The first memory cell-programming operation includes programming memory cells with the primary data in the at-least-one reduced read-frequency zone in accordance with a primary data-programming scheme. The first memory cell-reading operation includes reading programmed memory cells in the at-least-one reduced read-frequency zone. The lower logical pages in the at-least-one reduced read-frequency zone require fewer read operations than upper logical pages of the plurality of logical pages in the at-least-one reduced read-frequency zone to read the primary data.

In some embodiments, the method further includes a first secondary data-routing operation and a second memory cell-programming operation. The first secondary data-routing operation includes routing the secondary data to the upper logical pages in the at-least-one reduced read-frequency zone in accordance with the logical-to-physical address translator. The second memory cell-programming operation includes programming the memory cells in the at-least-one reduced read-frequency zone with the secondary data in accordance with the primary data-programming scheme.

In some embodiments, the first memory cell-programming operation includes stepwise programming the memory cells in the at-least-one reduced read-frequency zone such that the primary data is represented by an LSB, an LMSB, or both the LSB and the LMSB of four-bit tuples. The second memory cell-programming operation includes stepwise programming the memory cells in the at-least-one reduced read-frequency zone such that the secondary data is represented by a UMSB, an MSB, or both the UMSB and the MSB of the four-bit tuples. The lower logical pages in the at-least-one reduced read-frequency zone include an LSB logical page and an LMSB logical page. The upper logical pages in the at-least-one reduced read-frequency zone include a UMSB logical page and an MSB logical page.

In some embodiments, the first memory cell-reading operation includes applying one reference voltage per memory cell to determine a value of the LSB from a corresponding LSB logical page, one or two reference voltages per memory cell to determine a value of the LMSB from a corresponding LMSB logical page, four or five reference voltages per memory cell to determine a value of the UMSB from a corresponding UMSB logical page, and seven or eight reference voltages per memory cell to determine a value of the MSB from a corresponding MSB logical page.

In some embodiments, the method further includes a second secondary data-routing operation, a third memory cell-programming operation, and a second memory cell-reading operation. The second secondary data-routing operation includes routing the secondary data, the uncharacterizable data, or a combination thereof in accordance with the logical-to-physical address translator to any combination of lower or upper logical pages of a plurality of logical pages in at least one standard read-frequency zone. The third memory cell-programming operation includes programming the memory cells in the at-least-one standard read-frequency zone in accordance with a secondary data-programming scheme. The second memory cell-reading operation includes reading programmed memory cells in the at-least-one standard read-frequency zone. The lower and upper logical pages in the at-least-one standard read-frequency zone require about a same number of read operations to read the secondary data, the uncharacterizable data, or the combination thereof.

In some embodiments, the third memory cell-programming operation includes stepwise programming the memory cells in the at-least-one standard read-frequency zone such that the secondary data, the uncharacterizable data, or the combination thereof is represented by any combination of an LSB, an LMSB, a UMSB, or an MSB of four-bit tuples. The lower logical pages in the at-least-one standard read-frequency zone include an LSB logical page and an LMSB logical page. The upper logical pages in the at-least-one standard read-frequency zone include a UMSB logical page and an MSB logical page.

In some embodiments, the second memory cell-reading operation includes applying three or four reference voltages per memory cell to determine a value of any bit of the LSB, the LMSB, the UMSB, or the MSB respectively from its corresponding LSB logical page, LMSB logical page, UMSB logical page, or MSB logical page.

These and other features of the concepts provided herein will become more apparent to those of skill in the art in view of the accompanying drawings and following description, which describe particular embodiments of such concepts in greater detail.

### DRAWINGS

FIG. 1 illustrates a solid-state storage device in accordance with some embodiments.

FIG. 2 illustrates a block diagram of the solid-state storage device of FIG. 1.

FIG. 3 illustrates a block diagram of components in a NAND-flash package in accordance with some embodiments.

FIG. 4 illustrates a circuit diagram for a NAND-flash block in accordance with some embodiments.

FIG. 5 illustrates a block diagram of a die of a NAND-flash package having two read-frequency zones in accordance with some embodiments.

FIG. 6 illustrates logical pages for a NAND-flash block in accordance with some embodiments.

FIG. 7 illustrates a diagram of threshold-voltage distributions for three-bit tuples of a triple-level memory cell in accordance with some embodiments.

FIG. 8 illustrates a diagram of threshold-voltage distributions for four-bit tuples of a quad-level memory cell in accordance with some embodiments.

FIG. 9 illustrates a data center using solid-state storage devices in accordance with some embodiments.

### DESCRIPTION

Before some particular embodiments are disclosed in greater detail, it should be understood that the particular embodiments disclosed herein do not limit the scope of the concepts provided herein. It should also be understood that a particular embodiment disclosed herein can have features that can be readily separated from the particular embodiment and optionally combined with or substituted for features of any of a number of other embodiments disclosed herein.

Regarding terms used herein, it should also be understood the terms are for the purpose of describing some particular embodiments, and the terms do not limit the scope of the concepts provided herein. Ordinal numbers (e.g., first, second, third, etc.) are generally used to distinguish or identify different features or steps in a group of features or steps, and do not supply a serial or numerical limitation. For example, “first,” “second,” and “third” features or steps need not necessarily appear in that order, and the particular embodiments including such features or steps need not necessarily be limited to the three features or steps. Labels such as “left,” “right,” “top,” “bottom,” “front,” “back,” and the like are used for convenience and are not intended to imply, for example, any particular fixed location, orientation, or direction. Instead, such labels are used to reflect, for example, relative location, orientation, or directions. Singular forms of “a,” “an,” and “the” include plural references unless the context clearly dictates otherwise.

Unless defined otherwise, all technical and scientific terms used herein have the same meaning as commonly understood by those of ordinary skill in the art.

As set forth above, solid-state storage devices are needed that overcome the disadvantages of newer solid-state storage devices such as those including TLC or QLC NAND-flash packages without reducing storage capacity. Disclosed herein are solid-state storage devices and methods thereof for RTS data that address at least the foregoing.

### Solid-State Storage Devices

Solid-state storage devices provided herein are configured to reduce read time for read time-sensitive data (again “RTS data”), as well as reduce read-disturb effects for the RTS data.

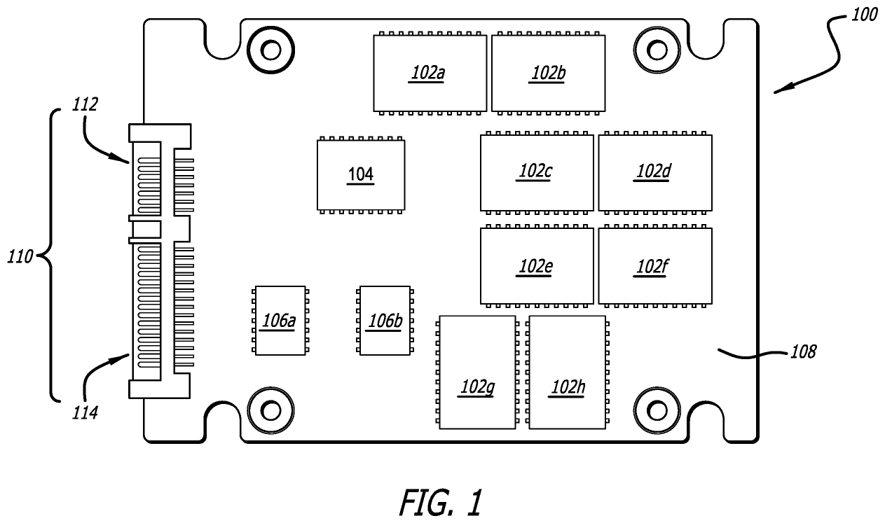

FIG. 1 illustrates a solid-state storage device 100 in accordance with some embodiments.

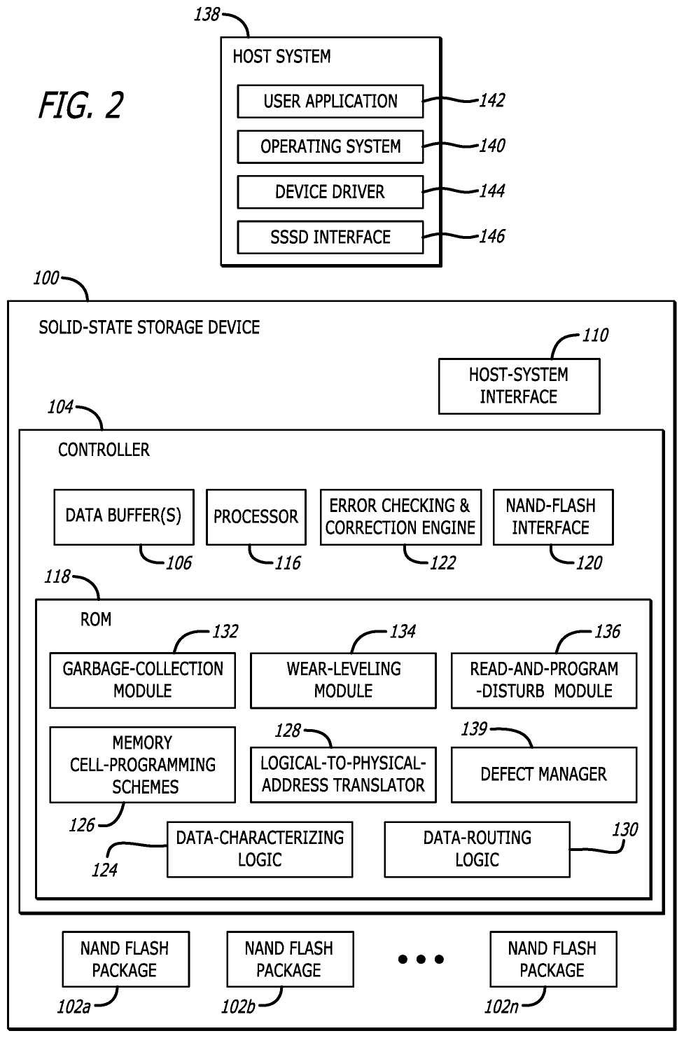

As shown, the solid-state storage device 100 includes one or more NAND-flash packages 102 (e.g., any one or more of NAND-flash packages 102a, 102b, . . . , 102n), a controller 104, and one or more buffers 106 (e.g., any one or more of buffers 106a, 106b, . . . , 106n) disposed on a printed circuit board 108. Instead of independently packaged buffers 106 such as those shown disposed on the printed circuit board 108, the one-or-more buffers 106 can be packaged with the controller 104. The solid-state storage device 100 also includes a host-system interface 110 having a data connector 112 and a power connector 114 configured to connect the solid-state storage device 100 to the host system 138. (See FIG. 2.) While not shown in detail, the one-or-more NAND-flash packages 102, the controller 104, the one-or-more buffers 106, and the host-system interface 110 are connected together with one or more busses.

It should be understood that solid-state storage devices provided herein are not limited to the solid-state storage device 100 or the form factor (e.g., 2.5-inch SATA solid-state drive) thereof. Indeed, the solid-state storage device 100 is merely one example of a solid-state storage device in which the concepts provided herein can be embodied. That said, the concepts provided herein are preferably embodied in solid-state storage devices that can store multiple bits of data per memory cell such as those including TLC, QLC, or penta-level cell (“PLC”) NAND-flash packages, with the solid-state storage devices including QLC or PLC NAND-flash packages deriving the most benefit.

FIG. 2 illustrates a block diagram of the solid-state storage device 100 in accordance with some embodiments.

Again, the solid-state storage device 100 includes the one-or-more NAND-flash packages 102, the controller 104, the one-or-more buffers 106, and the host-system interface 110 connected together with one or more busses. The one-or-more NAND-flash packages 102, the controller 104, the one-or-more buffers 106, and the host-system interface 110 are described, in turn, below; however, some crossover between the description exists in view of the interrelatedness of the one-or-more NAND-flash packages 102, the controller 104, the one-or-more buffers 106, and the host-system interface 110 in the solid-state storage device 100.

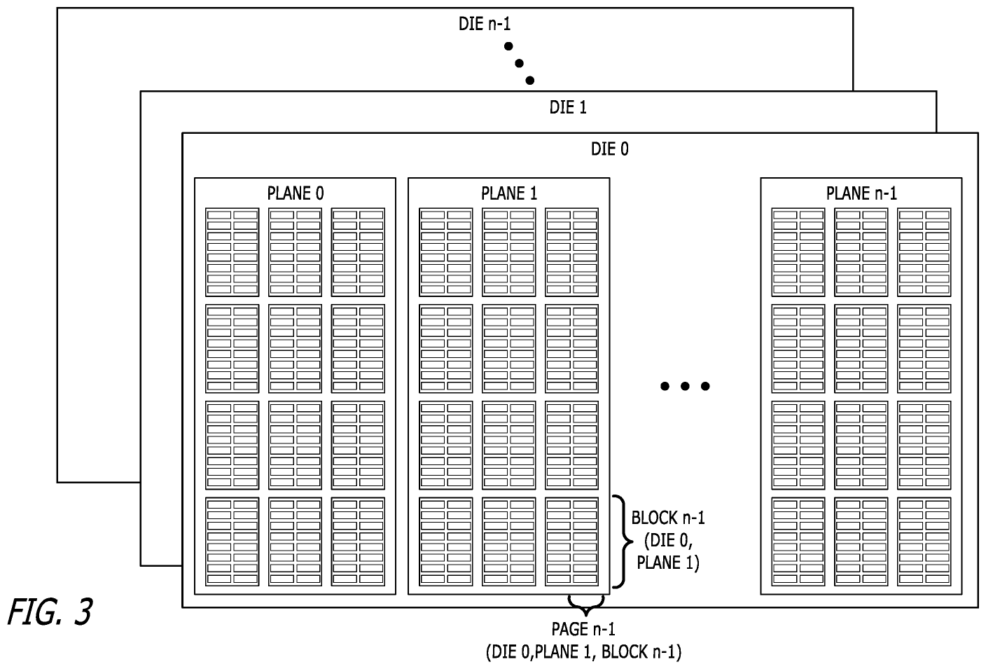

FIG. 3 illustrates a block diagram of components in a NAND-flash package of the one-or-more NAND-flash packages 102 in accordance with some embodiments.

As shown, each NAND-flash package of the one-or-more NAND-flash packages 102 includes one or more dies (e.g., die 0, die 1, die 2, . . . , die n−1). Each die of the one-or-more dies includes one or more planes (e.g., plane 0, plane 1, plane 2, . . . , plane n−1). Each plane of the one-or-more planes includes a plurality of blocks (e.g., block 0, block 1, block 2, . . . , block n−1), a block being the smallest erasable unit. And each block of the plurality of blocks includes a plurality of physical pages (e.g., page 0, page 1, page 2, . . . , page n−1), a page being the smallest writable unit.

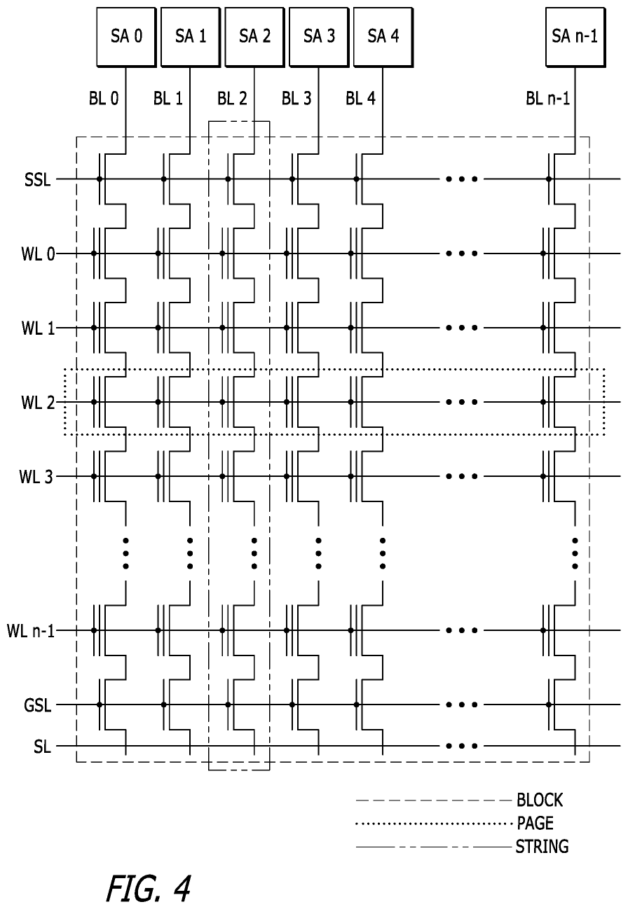

FIG. 4 illustrates a circuit diagram for a NAND-flash block in accordance with some embodiments.

As shown, each block of the plurality of blocks includes an array of floating-gate metal oxide-semiconductor field-effect transistor (“FG-MOSFET”)-based memory cells formed by a plurality of word lines (e.g., WL 0, WL 1, WL 2, . . . , WL n−1) intersecting with a plurality of bit lines (e.g., BL 0, BL 1, BL 2, . . . , BL n−1). The plurality of word lines define the plurality of physical pages, and the plurality of bit lines likewise form a plurality of strings.

Notably, each physical page of the foregoing word line-defined physical pages can have one or more corresponding logical pages; hence, “physical pages” and “logical pages” are differentiated herein. For example, MLC-based NAND-flash packages 102 can store up to two bits of data per memory cell represented by a two-bit tuple of four possible two-bit tuples formed of a least significant bit (again “LSB”) and a most significant bit (again “MSB”), each two-bit tuple representing a different threshold voltage Vₜh. Memory cells in a physical page of an MLC-based NAND-flash package can be logically combined to form an LSB logical page and an MSB logical page.

Each string of the foregoing bit line-defined strings is connected by its bit line to a shared source line (“SL”) at one end, whereas each string is connected by its bit line to a dedicated sense amplifier (“SA”) (e.g., SA 0, SA 1, SA 2, . . . , SA n−1) at the other end. Such a sense amplifier is configured for reading the threshold voltage Vₜₕ of a selected memory cell of a string during a read operation. A shared ground select line (“GSL”) and a shared string select line (“SSL”) are at opposing end portions of the strings. Specifically, each string includes a ground-select-line transistor having a gate connected to the ground select line and a string-select-line transistor having a gate connected to the string select line, the foregoing transistors configured to control string operations by switching them on or off. For example, the ground-select-line transistor is used to ground the bit line of a string for a selected memory cell during a read operation.

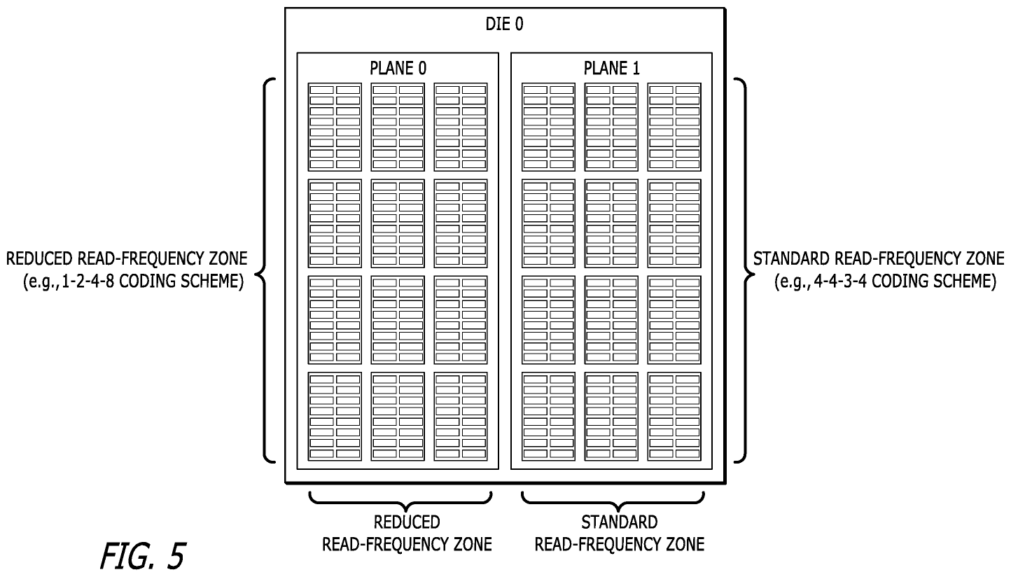

FIG. 5 illustrates a block diagram of a die of a NAND-flash package having two read-frequency zones in accordance with some embodiments.

As set forth above, solid-state storage devices provided herein are configured to reduce read time for RTS data, as well as reduce read-disturb effects for the RTS data. This is effectuated in solid-state storage devices such as the solid-state storage device 100 with two or more memory-cell programming schemes to respectively establish two or more read-frequency zones. The two-or-more read-frequency zones include at least one reduced read-frequency zone for primary data including the RTS data and at least one standard read-frequency zone for secondary data including non-RTS data, uncharacterizable data, or a combination thereof. The reduced read-frequency zone requires fewer read operations (e.g., one or two read operations) per bit of the primary data in the reduced read-frequency zone, thereby reducing read time for the primary data in the reduced read-frequency zone. In a trade-off, the reduced read-frequency zone requires more read operations (e.g., four to eight read operations) per bit of the secondary data in the reduced read-frequency zone, thereby increasing read time for the secondary data in the reduced read-frequency zone. The standard read-frequency zone requires about a same number of read operations per bit of the secondary data in the reduced read-frequency zone. As set forth in more detail below, the TLC-based NAND-flash packages 102 require two or three read operations per bit of the secondary data in the reduced read-frequency zone, the QLC-based NAND-flash packages 102 require three or four read operations per bit of the secondary data in the reduced read-frequency zone, and the PLC-based NAND-flash packages 102 require six or seven read operations per bit of the secondary data in the reduced read-frequency zone.

The two-or-more read-frequency zones can be established within at least one die of the one-or-more dies of the one-or-more NAND-flash packages 102. Given the foregoing two-or-more read-frequency zones, this results in at least one reduced read-frequency zone and at least one standard read-frequency zone within the at-least-one die. For example, a first plane and a second plane of the at-least-one die can respectively include the at-least-one reduced read-frequency zone and the at-least-one standard read-frequency zone. Alternatively, the two-or-more read-frequency zones can be established between at least two different dies of the one-or-more NAND-flash packages 102. This results in each die of the at-least-two different dies having a different read-frequency zone of the two-or-more read-frequency zones. For example, a first die and a second die of two NAND-flash packages 102 can respectively include the reduced read-frequency zone and the standard read-frequency zone of the foregoing two-or-more read-frequency zones.

Notably, the solid-state storage devices provided herein are not hybridized solid-state storage devices (e.g., a hybrid solid-state storage device including both SLC and TLC NAND-flash packages); that is, the solid-state storage devices are generally configured such that all blocks of memory cells have a same storage capacity. Examples of such solid-state storage devices are set forth below.

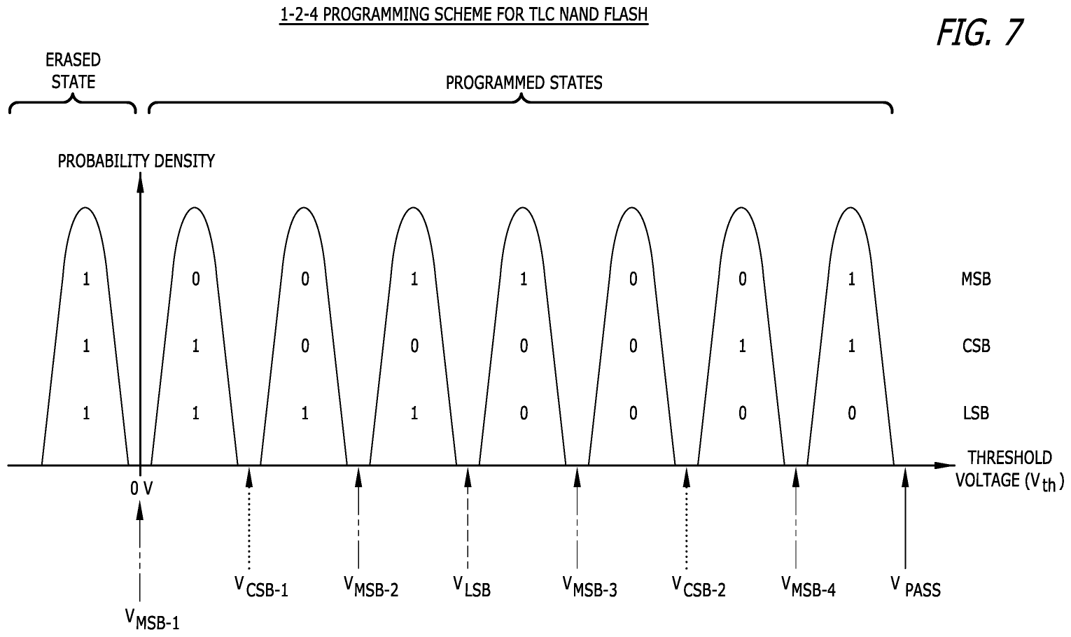

In an example, the solid-state storage devices can include one or more TLC-based NAND-flash packages 102 that can store up to three bits of data per memory cell. The three bits of data per memory cell are represented by a three-bit tuple of eight possible three-bit tuples, which, in turn, correspond to eight possible states of the memory cell, namely an erased state of the memory cell and up to seven programmed states of the memory cell. The eight different states of the memory cell correspond to eight different amounts of floating gate-trapped electrons having eight different readable threshold voltages. Each three-bit tuple of the eight possible three-bit tuples is formed of an LSB, a center significant bit (“CSB”), and an MSB, each three-bit tuple representing a different threshold voltage Vₜh. (See FIG. 7.) The LSB is considered a lower significant bit of the three-bit tuple, and the MSB is considered an upper significant bit of the three-bit tuple. The CSB can be considered either a lower significant bit of the three-bit tuple or an upper significant bit of the three-bit tuple. Like that set forth above with respect to the MLC-based NAND-flash packages 102, memory cells in a physical page of a TLC-based NAND-flash package can be logically combined to form an LSB logical page, a CSB logical page, and an MSB logical page.

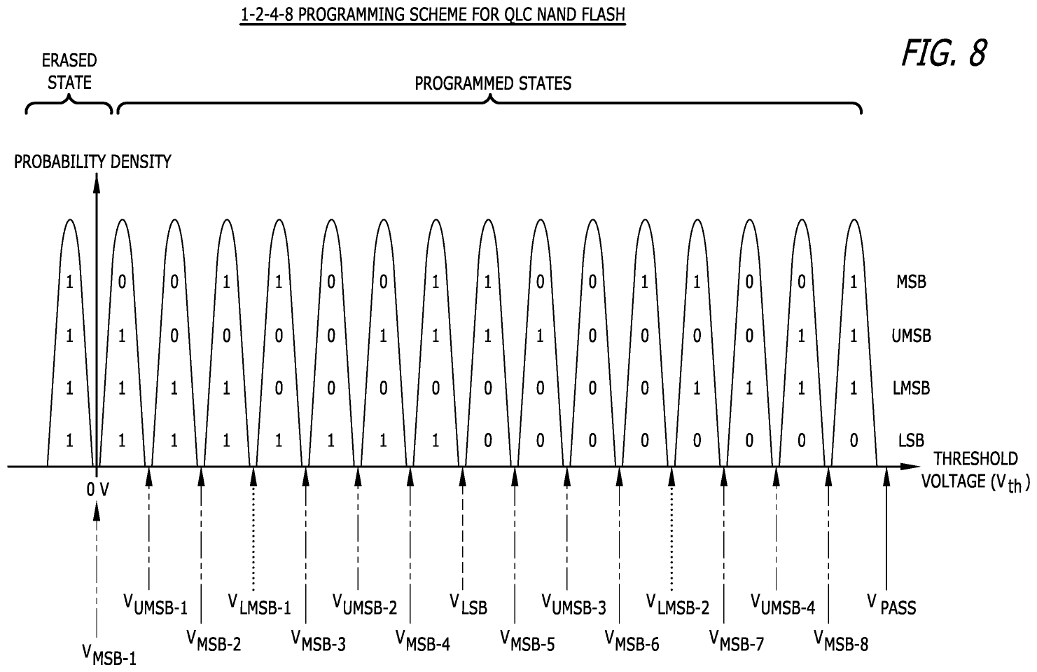

In another example, the solid-state storage devices can include one or more QLC-based NAND-flash packages 102 that can store up to four bits of data per memory cell. The four bits of data per memory cell are represented by a four-bit tuple of sixteen possible four-bit tuples, which, in turn, correspond to sixteen possible states of the memory cell, namely an erased state of the memory cell and up to fifteen programmed states of the memory cell. The sixteen different states of the memory cell correspond to sixteen different amounts of floating gate-trapped electrons having sixteen different readable threshold voltages. Each four-bit tuple of the sixteen possible four-bit tuples is formed of an LSB, a lower-middle significant bit (again “LMSB”), an upper-middle significant bit (again “UMSB”), and an MSB, each four-bit tuple representing by a different threshold voltage Vₜₕ. (See FIG. 8.) The LSB and the LMSB are considered lower significant bits of the four-bit tuple, and the UMSB and the MSB are considered upper significant bits of the four-bit tuple. Memory cells in a physical page of a QLC-based NAND-flash package can be logically combined to form an LSB logical page, an LMSB logical page, a UMSB logical page, and an MSB logical page.

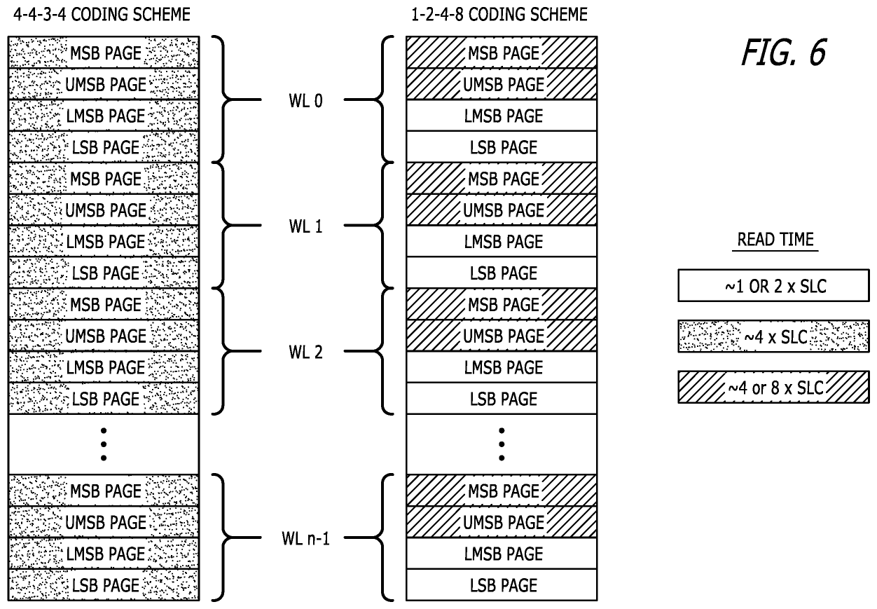

FIG. 6 illustrates logical pages for a QLC-based NAND-flash package in accordance with the foregoing embodiment.

As shown, the memory cells in a physical page of the QLC-based NAND-flash package can be logically combined to form an LSB logical page, an LMSB logical page, a UMSB logical page, and an MSB logical page. As set forth in more detail below with respect to the 1-2-4-8 programming scheme, determining a value of the LSB from a corresponding LSB logical page includes applying one reference voltage per memory cell, determining a value of the LMSB from a corresponding LMSB logical page includes applying two reference voltages per memory cell, determining a value of the UMSB from a corresponding UMSB logical page includes applying four reference voltages per memory cell, and determining a value of the MSB from a corresponding MSB logical page includes applying eight reference voltages per memory cell. In contrast, determining any value of the LSB, the LMSB, the UMSB, or the MSB from its corresponding logical page under the 4-4-3-4 programming scheme includes applying three or four reference voltages per memory cell.

In yet another example, the solid-state storage devices can include one or more PLC-based NAND-flash packages 102 that can store up to five bits of data per memory cell. The five bits of data per memory cell are represented by a five-bit tuple of thirty-two possible five-bit tuples, which, in turn, correspond to thirty-two possible states of the memory cell, namely an erased state of the memory cell and up to thirty-one programmed states of the memory cell. The thirty-two different states of the memory cell correspond to thirty-two different amounts of floating gate-trapped electrons having thirty-two different readable threshold voltages. Each five-bit tuple of the thirty-two possible five-bit tuples is formed of an LSB, an LMSB, ac CSB, a UMSB, and an MSB, each five-bit tuple representing a different threshold voltage Vₜₕ. (See FIG. 8.) The LSB and the LMSB are considered lower significant bits of the five-bit tuple, and the UMSB and the MSB are considered upper significant bits of the five-bit tuple. The CSB can be considered either a lower significant bit of the five-bit tuple or an upper significant bit of the five-bit tuple. Memory cells in a physical page of a PLC-based NAND-flash package can be logically combined to form an LSB logical page, an LMSB logical page, a CSB logical page, a UMSB logical page, and an MSB logical page.

FIG. 6 illustrates logical pages for a block in a QLC-based NAND-flash package in accordance with some embodiments.

As set forth in more detail below with respect to the controller 104, the data routing logic is configured for routing the primary data including the RTS data to a plurality of physical pages in a reduced read-frequency zone having corresponding lower logical pages of a plurality of logical pages. In addition, the data routing logic is configured for routing the secondary data including the non-RTS data to upper logical pages of the foregoing plurality of logical pages. Such lower logical pages include the LSB logical pages of the TLC-, QLC-, and PLC-based NAND-flash packages 102, as well as the LMSB logical pages of the QLC- and PLC-based NAND-flash packages 102. Such upper logical pages include the MSB logical pages of the TLC-, QLC-, and PLC-based NAND-flash packages 102, as well as the UMSB logical pages of the QLC- and PLC-based NAND-flash packages 102. While the CSB logical pages of the TLC- and PLC-based NAND-flash packages 102 can be grouped with either of the foregoing lower or upper logical pages, more of a reduction in read time is realized when the CSB logical pages are grouped with the upper logical pages. The lower logical pages require fewer read operations than the upper logical pages to read the primary data in a reduced read-frequency zone, which results in a reduction of read time and read-disturb effects for the RTS data.

Again, FIG. 2 illustrates a block diagram of the solid-state storage device 100 including the controller 104 in accordance with some embodiments.

The controller 104 includes a processor 116, read-only memory (“ROM”) 118, and a NAND-flash interface 120. In addition, the controller 104 includes an error checking-and-correction (“ECC”) engine 122.

The processor 116 is configured to decode commands and execute tasks from the host system 138 or firmware of the ROM 118, as well as handle data flow to and from the NAND-flash packages 102. The processor 116 can be based upon principles or specifications for a reduced instruction-set computer (“RISC”). That is, the processor 116 can be a RISC-based processor such as a RISC-V processor.

The ROM 118 is configured to include the firmware of the controller 104. Such firmware includes data-characterizing logic 124, memory cell-programming schemes 126, a logical-to-physical-address translator 128, data-routing logic 130, a garbage-collection module 132, and a wear-leveling module 134. Optionally, the firmware includes a read-and-program-disturb module 136, a defect manager 139, or both. The read-and-program-disturb module 136 is configured to compensate for cross coupling of memory cells during reading or writing operations using one or more algorithms therefor. The defect manager 139 is configured to maintain a table or map of bad blocks such that write operations are not carried out on the bad blocks. The ROM 118 can be electrically erasable, programmable ROM (“EEPROM”).

The data-characterizing logic 124 can be configured to characterize incoming data from the host system 138 as primary data including the RTS data, secondary data including non-RTS data, or uncharacterizable data with rules therefor. In addition, the data-characterizing logic 124 can be configured to recharacterize stored data on the solid-state storage device 100 in accordance with metadata (e.g., data-access metadata) for the stored data, thereby allowing recharacterization of, for example, any stored secondary data or uncharacterizable data as primary data or any stored primary data as secondary data. Such recharacterization is useful when redistributing stored data across the solid-state storage device 100 in accordance with garbage-collection and wear-leveling processes.

The data-characterizing logic 124 can be configured to characterize the incoming data from the host system 138 as likely to be frequently accessed data or seldomly accessed data. When so configured, the primary data further includes the likely-to-be frequently accessed data, and the secondary data further includes the likely-to-be seldomly accessed data.

The memory-cell programming schemes 126 are configured to establish two or more read-frequency zones in solid-state storage devices such as the solid-state storage device 100. This is effectuated with two or more memory-cell programming schemes 126 including a primary data-programming scheme and a secondary data-programming scheme. Indeed, the primary data-programming scheme is used to establish at least one reduced read-frequency zone for the primary data. The secondary data-programming scheme is used to establish at least one standard read-frequency zone for the secondary data, uncharacterizable data, or a combination thereof.

The primary data-programming scheme is configured for programming the memory cells in the at-least-one reduced read-frequency zone such that the primary data is represented by lower significant bits of multi-bit tuples in lower logical pages of a plurality of logical pages. In TLC-based NAND-flash packages 102, for example, the primary data-programming scheme is configured for programming the memory cells in the at-least-one reduced read-frequency zone such that the primary data is represented by the lower significant bits (e.g., the LSB, the CSB, or both) of the three-bit tuples in the lower logical pages (e.g., the LSB logical page, the CSB logical page, or both) of the three logical pages (e.g., the LSB logical page, the CSB logical page, and the MSB logical page). In QLC-based NAND-flash packages 102, for example, the primary data-programming scheme is configured for programming the memory cells in the at-least-one reduced read-frequency zone such that the primary data is represented by the lower significant bits (e.g., the LSB and the LMSB) of the four-bit tuples in the lower logical pages (e.g., the LSB logical page and the LMSB logical page) of the four logical pages (e.g., the LSB logical page, the LMSB logical page, the UMSB logical, and the MSB logical page). In PLC-based NAND-flash packages 102, for example, the primary data-programming scheme is configured for programming the memory cells in the at-least-one reduced read-frequency zone such that the primary data is represented by the lower significant bits (e.g., the LSB, the LMSB, the CSB, or a combination thereof) of the five-bit tuples in the lower logical pages (e.g., the LSB logical page, LMSB logical page, the CSB logical page, or a combination thereof) of the five logical pages (e.g., the LSB logical page, the LMSB logical page, the CSB logical page, the UMSB logical page, and the MSB logical page). The lower significant bits in the reduced read-frequency zone require only one or two read operations per memory cell to determine their values, thereby decreasing read time for the primary data in the reduced read-frequency zone. (See FIGS. 7 and 8.)

The primary data-programming scheme is configured for programming the memory cells in the at-least-one reduced read-frequency zone such that the secondary data is represented by upper significant bits of the multi-bit tuples in upper logical pages of the plurality of logical pages. In TLC-based NAND-flash packages 102, for example, the primary data-programming scheme is configured for programming the memory cells in the at-least-one reduced read-frequency zone such that the secondary data is represented by the upper significant bits (e.g., the CSB, the MSB, or both) of the three-bit tuples in the upper logical pages (e.g., the CSB logical page, the MSB logical page, or both) of the three logical pages (e.g., the LSB logical page, the CSB logical page, and the MSB logical page). In QLC-based NAND-flash packages 102, for example, the primary data-programming scheme is configured for programming the memory cells in the at-least-one reduced read-frequency zone such that the secondary data is represented by the upper significant bits (e.g., the UMSB and the MSB) of the four-bit tuples in the upper logical pages (e.g., the UMSB logical page and the MSB logical page) of the four logical pages (e.g., the LSB logical page, the LMSB logical page, the UMSB logical, and the MSB logical page). In PLC-based NAND-flash packages 102, for example, the primary data-programming scheme is configured for programming the memory cells in the at-least-one reduced read-frequency zone such that the secondary data is represented by the upper significant bits (e.g., the CSB, the UMSB, the MSB, or a combination thereof) of the five-bit tuples in the upper logical pages (e.g., the CSB logical page, UMSB logical page, the MSB logical page, or a combination thereof) of the five logical pages (e.g., the LSB logical page, the LMSB logical page, the CSB logical page, the UMSB logical page, and the MSB logical page). In a trade-off, the upper significant bits in the reduced read-frequency zone require four to eight read operations per memory cell to determine their values, thereby increasing read time for the secondary data in the reduced read-frequency zone. For this reason, the secondary data should not include uncharacterizable data, which can include unknown RTS data until recharacterized in accordance with garbage-collection and wear-leveling processes.

The secondary data-programming scheme is configured for programming the memory cells in the at-least-one standard read-frequency zone such that the secondary data, the uncharacterizable data, or the combination thereof is represented by any combination of significant bits of multi-bit tuples in a plurality of logical pages. In TLC-based NAND-flash packages 102, for example, the secondary data-programming scheme is configured for programming the memory cells in the at-least-one standard read-frequency zone such that the foregoing data is represented by any combination of the LSB, the CSB, and the MSB of the three-bit tuples in the three logical pages of the LSB logical page, the CSB logical page, and the MSB logical page. In QLC-based NAND-flash packages 102, for example, the secondary data-programming scheme is configured for programming the memory cells in the at-least-one standard read-frequency zone such that the foregoing data is represented by any combination of the LSB, the LMSB, the UMSB, and the MSB of the four-bit tuples in the four logical pages of the LSB logical page, the LMSB logical page, the UMSB logical page, and the MSB logical page. In PLC-based NAND-flash packages 102, for example, the secondary data-programming scheme is configured for programming the memory cells in the at-least-one standard read-frequency zone such that the foregoing data is represented by any combination of the LSB, the LMSB, the CSB, the UMSB, and the MSB of the five-bit tuples in the five logical pages of the LSB logical page, the LMSB logical page, the CSB logical page, the UMSB logical page, and the MSB logical page. For TLC-based NAND-flash packages 102, each bit of the LSB, the CSB, and the MSB of a same or different three-bit tuple requires two or three read operations per memory cell to determine its value. For QLC-based NAND-flash packages 102, each bit of the LSB, the LMSB, the UMSB, and the MSB of a same or different four-bit tuple requires three or four read operations per memory cell to determine its value. For QLC-based NAND-flash packages 102, each bit of the LSB, the LMSB, the CSB, the UMSB, and the MSB of a same or different five-bit tuple requires six or seven read operations per memory cell to determine its value.

FIG. 7 illustrates a diagram of threshold-voltage distributions for the three-bit tuples of a triple-level memory cell in accordance with some embodiments.

One or more TLC-based NAND-flash packages 102 in a solid-state storage device such as the solid-state storage device 100 can have, for example, a 1-2-4 programming scheme for the primary data-programming scheme and a 2-2-3 programming scheme for the secondary data-programming scheme.

The 1-2-4 programming scheme is configured for programming the memory cells in the at-least-one reduced read-frequency zone such that the primary data (e.g., the RTS data) is represented by the LSB and, optionally, the CSB. In addition, the secondary data (e.g., the non-RTS data) is represented by the MSB and, optionally, the CSB if not used for the primary data. As shown, reading the LSB from any given memory cell in the at-least-one reduced read-frequency zone requires one read operation, which includes application of one reference voltage V_{LSB} to determine whether the LSB has a value 0 or 1. Reading the CSB from a same or different memory cell in the at-least-one reduced read-frequency zone requires two read operations, which include application of two reference voltages V_{CSB-1} and V_{CSB-2} to determine whether the CSB has a value 0 or 1. The trade-off of the 1-2-4 programming scheme is that reading the MSB from the same or different memory cell in the at-least-one reduced read-frequency zone requires four read operations, which include application of four reference voltages V_{MSB-1}, V_{MSB-2}, V_{MSB-3}, and V_{MSB-4} to determine whether the MSB has a value 0 or 1. Thus, the read time for the primary data in the at-least-one reduced read-frequency zone with the 1-2-4 programming scheme can be reduced to that for a single-level memory cell, whereas the read time for the secondary data in the same reduced read-frequency zone is concomitantly increased to four times that for a single-level memory cell. (See Table 1 below.)

The 2-2-3 programming scheme is configured for programming the memory cells in the at-least-one standard read-frequency zone such that the secondary data (e.g., the non-RTS data), the uncharacterizable data, or the combination thereof is represented by any combination of the LSB, the CSB, and the MSB. While not shown, reading the LSB from any given memory cell in the at-least-one standard read-frequency zone requires two read operations, which include application of two reference voltages V_{LSB-1} and V_{LSB-2} to determine whether the LSB has a value 0 or 1. Likewise, reading the CSB from a same or different memory cell in the at-least-one standard read-frequency zone requires two read operations, which include application of two reference voltages V_{CSB-1} and V_{CSB-2} to determine whether the CSB has a value 0 or 1. Reading the MSB from the same or different memory cell in the at-least-one standard read-frequency zone requires three read operations, which include application of three reference voltages V_{MSB-1}, V_{MSB-2}, and V_{MSB-3} to determine whether the MSB has a value 0 or 1. Thus, the read time for the secondary data or uncharacterizable data in the at-least-one standard read-frequency zone with the 2-2-3 programming scheme is two to three times that for a single-level memory cell. (See Table 1 below.)

TABLE 1
Read times for 1-2-4 and 2-2-3 programming schemes for triple-
level memory cells relative to single-level memory cells.

| 1-2-4 Programming Scheme | | 2-2-3 Programming Scheme | |
|---|---|---|---|
| Bit of 3-Bit Tuple | Read Time | Bit of 3-Bit Tuple | Read Time |
| LSB | ~1 × SLC | LSB | ~2 × SLC |
| CSB | ~2 × SLC | CSB | ~2 × SLC |
| MSB | ~4 × SLC | MSB | ~3 × SLC |

FIG. 8 illustrates a diagram of threshold-voltage distributions for the four-bit tuples of a quad-level memory cell in accordance with some embodiments.

One or more QLC-based NAND-flash packages 102 in a solid-state storage device such as the solid-state storage device 100 can have, for example, a 1-2-4-8 programming scheme for the primary data-programming scheme and a 4-4-3-4 programming scheme for the secondary data-programming scheme.

The 1-2-4-8 programming scheme is configured for programming the memory cells in the at-least-one reduced read-frequency zone such that the primary data (e.g., the RTS data) is represented by the LSB and LMSB. In addition, the secondary data (e.g., the non-RTS data) is represented by the UMSB and the MSB. As shown, reading the LSB from any given memory cell in the at-least-one reduced read-frequency zone requires one read operation, which includes application of one reference voltage V_{LSB} to determine whether the LSB has a value 0 or 1. Reading the LMSB from a same or different memory cell in the at-least-one reduced read-frequency zone requires two read operations, which include application of two reference voltages V_{LMSB-1} and V_{LMSB-2} to determine whether the LMSB has a value 0 or 1. The trade-off of the 1-2-4-8 programming scheme is that reading the UMSB from the same or different memory cell in the at-least-one reduced read-frequency zone requires four read operations, which include application of four reference voltages V_{UMSB-1}, V_{UMSB-2}, V_{UMSB-3}, and V_{UMSB-4} to determine whether the UMSB has a value 0 or 1. In addition, reading the MSB from the same or different memory cell in the at-least-one reduced read-frequency zone requires eight read operations, which include application of eight reference voltages V_{MSB-1}, V_{MSB-2}, V_{MSB-3}, V_{MSB-4}, V_{MSB-5}, V_{MSB-6}, V_{MSB-7}, and V_{MSB-8} to determine whether the MSB has a value 0 or 1. Thus, the read time for the primary data in the at-least-one reduced read-frequency zone with the 1-2-4-8 programming scheme can be reduced to once or twice that for a single-level memory cell, whereas the read time for the secondary data in the same reduced read-frequency zone is concomitantly increased to four or eight times that for a single-level memory cell. (See Table 2 below.)

The 4-4-3-4 programming scheme is configured for programming the memory cells in the at-least-one standard read-frequency zone such that the secondary data (e.g., the non-RTS data), the uncharacterizable data, or the combination thereof is represented by any combination of the LSB, the LMSB, the UMSB, and the MSB. While not shown, reading the LSB from any given memory cell in the at-least-one standard read-frequency zone requires four read operations, which include application of four reference voltages V_{LSB-1}, V_{LSB-2}, V_{LSB-3}, and V_{LSB-4} to determine whether the LSB has a value 0 or 1. Likewise, reading the LMSB from a same or different memory cell in the at-least-one standard read-frequency zone requires four read operations, which include application of four reference voltages V_{LMSB-1}, V_{LMSB-2}, V_{LMSB-3}, and V_{LMSB-4} to determine whether the LMSB has a value 0 or 1. Reading the UMSB from the same or different memory cell in the at-least-one standard read-frequency zone requires three read operations, which include application of three reference voltages V_{UMSB-1}, V_{UMSB-2}, and V_{UMSB-3} to determine whether the UMSB has a value 0 or 1. Lastly, reading the MSB from a same or different memory cell in the at-least-one standard read-frequency zone requires four read operations, which include application of four reference voltages V_{MSB-1}, V_{MSB-2}, V_{MSB-3}, and V_{MSB-4} to determine whether the MSB has a value 0 or 1. Thus, the read time for the secondary data or uncharacterizable data in the at-least-one standard read-frequency zone with the 4-4-3-4 programming scheme is three to four times that for a single-level memory cell. (See Table 2 below.)

TABLE 2
Read times for 1-2-4-8 and 4-4-3-4 programming schemes for quad-
level memory cells relative to single-level memory cells.

| 1-2-4-8 Programming Scheme | | 4-4-3-4 Programming Scheme | |
|---|---|---|---|
| Bit of 4-Bit Tuple | Read Time | Bit of 4-Bit Tuple | Read Time |
| LSB | ~1 × SLC | LSB | ~4 × SLC |
| LMSB | ~2 × SLC | LMSB | ~4 × SLC |
| UMSB | ~4 × SLC | UMSB | ~3 × SLC |
| MSB | ~8 × SLC | MSB | ~4 × SLC |

Other memory-cell programming schemes for the one-or-more QLC-based NAND-flash packages 102 in a solid-state storage device such as the solid-state storage device 100 include, for example, either a 1-2-5-7 programming scheme or a 1-1-5-8 programming scheme for the primary data-programming scheme and the foregoing 4-4-3-4 programming scheme for the secondary data-programming scheme. Like that described above for the 1-2-4-8 programming scheme, reading the data from any given memory cell in the at-least-one reduced read-frequency zone having a 1-2-5-7 programming scheme or a 1-1-5-8 programming scheme requires one read operation to determine whether the LSB has a value 0 or 1, one or two read operations to determine whether the LMSB has a value of 0 or 1, four or five read operations to determine whether the UMSB has a value of 0 or 1, and seven or eight read operations to determine whether the MSB has a value of 0 or 1. Thus, the read time for the primary data in the at-least-one reduced read-frequency zone with the 1-2-5-7 programming scheme or the 1-1-5-8 programming scheme can be reduced to once or twice that for a single-level memory cell, whereas the read time for the secondary data in the same reduced read-frequency zone is concomitantly increased to four, five, seven, or eight times that for a single-level memory cell.

Still other memory-cell programming schemes for the one-or-more QLC-based NAND-flash packages 102 in a solid-state storage device such as the solid-state storage device 100 include, for example, an 8-4-2-1 programming scheme for the primary data-programming scheme and the foregoing 4-4-3-4 programming scheme for the secondary data-programming scheme. Like that described above for the 1-2-4-8 programming scheme—albeit inversely thereof—reading the data from any given memory cell in the at-least-one reduced read-frequency zone having an 8-4-2-1 programming scheme requires one read operation to determine whether the MSB has a value 0 or 1, two read operations to determine whether the UMSB has a value of 0 or 1, four read operations to determine whether the LMSB has a value of 0 or 1, and eight read operations to determine whether the LSB has a value of 0 or 1. Thus, the read time for the primary data in the at-least-one reduced read-frequency zone with the 8-4-2-1 programming scheme can be reduced to once or twice that for a single-level memory cell, whereas the read time for the secondary data in the same reduced read-frequency zone is concomitantly increased to four or eight times that for a single-level memory cell.

The logical-to-physical-address translator 128 is configured to manage translation of logical addresses (e.g., addresses of logical pages) such as those used by the host system 138 to physical addresses (e.g., addresses of physical pages) such as those used by the solid-state storage device 100 and vice versa.

In accordance with a logical-to-physical address translator 128, the data routing logic is configured for routing the primary data to the plurality of physical pages corresponding to lower logical pages of a plurality of logical pages in the at-least-one reduced read-frequency zone. In addition, the data-routing logic 130 is configured for routing the secondary data to the plurality of physical pages corresponding to upper logical pages of the plurality of logical pages in the at-least-one reduced read-frequency zone. Lastly, the data-routing logic 130 is configured for routing the secondary data, the uncharacterizable data, or the combination thereof to a plurality of physical pages corresponding to any combination of upper and lower logical pages of a plurality of logical pages in the at-least-one standard read-frequency zone.

The garbage-collection module 132 is configured to erase erase-designated blocks of the plurality of blocks including invalid logical pages having invalid data (e.g., data marked as deleted by the host system 138) once valid data from the erase-designated block is redistributed by the wear-leveling module 134.

The wear-leveling module 134 is configured to evenly distribute the incoming data from the host system 138 in a plurality of memory cell-programming instances over erased blocks of the plurality of blocks in each zone of the at-least-one reduced read-frequency zone and the at-least-one standard read-frequency zone in accordance with characterization of the incoming data as primary data, secondary data, or uncharacterizable data. In addition, the wear-leveling module 134 is configured to evenly distribute valid data from valid logical pages of the erase-designated blocks in a plurality of memory cell-programming instances over erased blocks of the plurality of blocks in each zone of the at-least-one reduced read-frequency zone and the at-least-one standard read-frequency zone in accordance with any recharacterization of the valid data by the data-characterizing logic 124.

The NAND-flash interface 120 is configured to write incoming data from the host system 138 or data redistributed by the wear-leveling module 134. The NAND-flash interface 120 can be based upon principles or specifications set forth by the industry group known as the Open NAND Flash Interface (“ONFi”) Working Group. That is, the NAND-flash interface 120 can be an ONFi-based flash interface.

The ECC engine 122 is configured to reduce errors in at least read operations on memory cells, thereby ensuring data integrity. The ECC engine 122 can be specific hardware within the controller 104 including algorithms configured for detecting read errors, as well as ECC codes configured for correcting the read errors.

The one-or-more buffers 106 are configured to temporarily store incoming data from the system host or data redistributed by the wear-leveling module 134. Each of the one-or-more buffers 106 can be dynamic random-access memory (“DRAM”) including synchronous DRAM (“SDRAM”) such as double data-rate SDRAM (“DDR SDRAM”), for example, DDR3 SDRAM or DDR4 SDRAM, particularly when packaged independently of the controller 104.

The host-system interface 110 can be a serial advanced technology-attachment (“SATA”) interface such as that shown in FIG. 1, wherein the host-system interface 110 includes the data connector 112 and the power connector 114 configured to connect the solid-state storage device 100 to the host system 138.

FIG. 2 also shows the host system 138, which can be a personal computer. The host system 138 includes system software such as an operating system 140 and application software such as one or more user applications 142. A device driver 144 of the host system 138 is configured to provide a software interface to the solid-state storage device 100, thereby enabling the operating system 140, the one-or-more user applications 142, or a combination thereof to access functions of the solid-state storage device 100 through a solid-state storage-device interface 146 of the host system 138.

### Data Centers

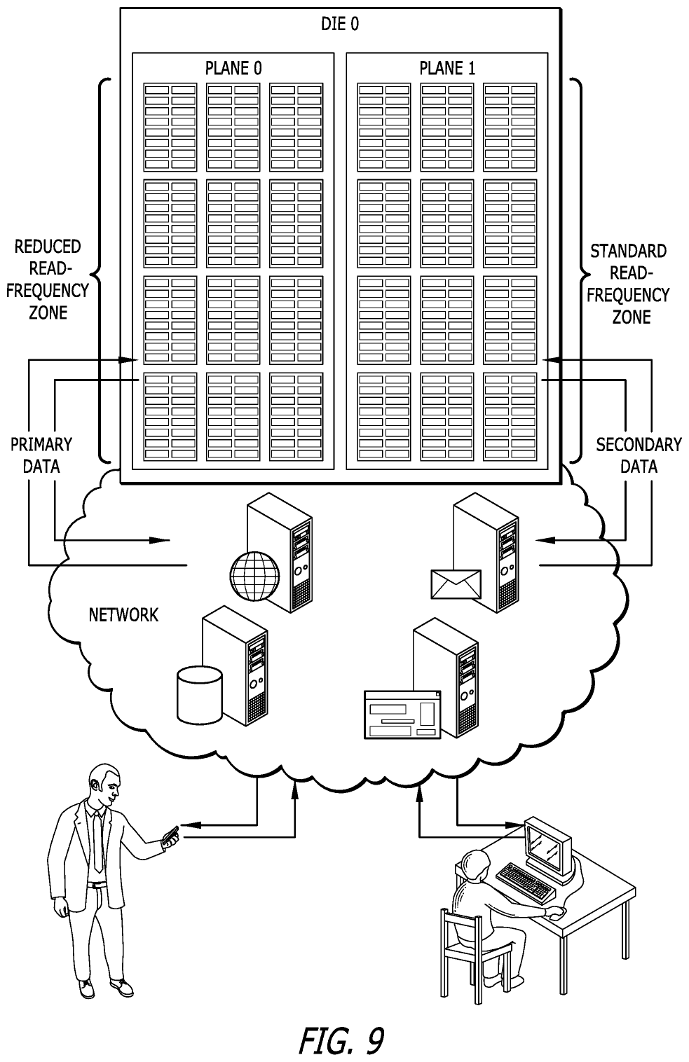

FIG. 9 illustrates a data center using solid-state storage devices in accordance with some embodiments.

As shown, data centers can use solid-state storage devices such as the foregoing solid-state storage devices to reduce read time for RTS data, as well as read-disturb effects for the RTS data. While the data centers can likewise employ two or more memory-cell programming schemes to respectively establish two or more read-frequency zones (e.g., the reduced read-frequency zone for the primary data and the standard read-frequency zone for the secondary data including non-RTS data, uncharacterizable data, or a combination thereof) in each solid-state storage device of a plurality of solid-state storage devices on a die-by-die or plane-by-plane basis in the NAND-flash packages thereof, the data centers can alternatively dedicate entire racks or entire rack-units to each memory-cell programming scheme of the two or more memory-cell programming schemes. Consequently, certain functions such as that of the data-characterizing logic 124 and the data-routing logic 130 are implemented by higher-level systems rather than by solid-state storage-device controllers such as the controller 104.

### Methods

Methods implemented by solid-state storage devices such as the solid-state storage device 100 include a method for reduced read time with respect to RTS data. Such a method includes an incoming data-characterizing operation, a primary data-routing operation, a first memory cell-programming operation, and a first memory cell-reading operation, each operation of which is described in more detail below for an example QLC-based solid-state storage device with a 1-2-4-8 programming scheme in at least one reduced read-frequency zone and a 4-4-3-4 programming scheme in at least one standard read-frequency zone. However, it should be understood that an analogous method can be implemented by a QLC-based solid-state storage device with different programming schemes or even a TLC- or PLC-based solid-state storage device in view of the description for those devices set forth above.

The incoming data-characterizing operation includes characterizing incoming data from the host system 138 as primary data including the RTS data, secondary data including non-RTS data, or uncharacterizable data. As set forth above, the incoming data-characterizing operation is performed by the data-characterizing logic 124 of the controller 104 of the solid-state storage device 100.

The primary data-routing operation includes routing the primary data in accordance with the logical-to-physical address translator 128 of the controller 104 to lower logical pages of a plurality of logical pages in at least one reduced read-frequency zone of the solid-state storage device 100. The plurality of logical pages in the at-least-one reduced read-frequency zone correspond to a plurality of word-line defined physical pages.

In addition to the primary data-routing operation, the method further includes a first secondary data-routing operation and a second secondary data-routing operation. The first secondary data-routing operation includes routing the secondary data to upper logical pages of a plurality of logical pages in the at-least-one reduced read-frequency zone in accordance with the logical-to-physical address translator 128. The second secondary data-routing operation includes routing the secondary data, the uncharacterizable data, or a combination thereof in accordance with the logical-to-physical address translator 128 to any combination of lower or upper logical pages of a plurality of logical pages in at least one standard read-frequency zone corresponding to another plurality of word-line defined physical pages.

The first memory cell-programming operation includes programming FG-MOSFET-based memory cells with the primary data in the at-least-one reduced read-frequency zone in accordance with the primary data-programming scheme (e.g., the 1-2-4-8 programming scheme). Such programming includes stepwise programming (e.g., “foggy-fine programming”) the memory cells in the at-least-one reduced read-frequency zone such that the primary data is represented by the LSB, the LMSB, or both the LSB and the LMSB of the four-bit tuples. As set forth above, the lower logical pages in the at-least-one reduced read-frequency zone include the LSB logical page and the LMSB logical page.

In addition to the first memory cell-programming operation, the method further includes a second memory cell-programming operation. The second memory cell-programming operation includes programming the memory cells in the at-least-one reduced read-frequency zone with the secondary data in accordance with the primary data-programming scheme. The second memory cell-programming operation includes stepwise programming (e.g., “foggy-fine programming”) the memory cells in the at-least-one reduced read-frequency zone such that the secondary data is represented by the UMSB, the MSB, or both the UMSB and the MSB of the four-bit tuples. As set forth above, the upper logical pages in the at-least-one reduced read-frequency zone include the UMSB logical page and the MSB logical page.

In addition to the first and second memory cell-programming operations, the method further includes a third memory cell-programming operation. The third memory cell-programming operation includes programming the memory cells in the at-least-one standard read-frequency zone in accordance with the secondary data-programming scheme (e.g., the 4-4-3-4 programming scheme). The third memory cell-programming operation includes stepwise programming (e.g., “foggy-fine programming”) the memory cells in the at-least-one standard read-frequency zone such that the secondary data, the uncharacterizable data, or the combination thereof is represented by any combination of the LSB, the LMSB, the UMSB, or the MSB of the four-bit tuples. As set forth above, the lower logical pages in the at-least-one standard read-frequency zone include the LSB logical page and the LMSB logical page while the upper logical pages in the at-least-one standard read-frequency zone include the UMSB logical page and the MSB logical page.

By way of example, any memory cell-programming operation of the first, second, and third memory cell-programming operations includes—for any single memory cell selected for programming—applying one or more relatively high-voltage programming pulses to the control gate of the memory cell being programmed while applying a pass-through voltage V to each pass control gate of the control gates of the other memory cells along the same bit line. During the one-or-more programming pulses, electrons tunnel into the floating gate of the memory cell being programmed in accordance with a targeted threshold voltage for the memory cell. The stepwise-programming aspect of such programming includes applying more than one programming pulse, each successive programming pulse of the programming pulses having a successively narrower voltage window to set the voltage distribution for, in the instant case of a QLC-based solid-state storage device, the LSB, the LMSB, the UMSB, and the MSB of the four-bit tuple of the memory cell being programmed.

The first memory cell-reading operation includes reading programmed memory cells in the at-least-one reduced read-frequency zone. As set forth above, the lower logical pages of the primary data require fewer read operations than the upper logical pages of the secondary data in the at-least-one reduced read-frequency zone to read, which results in the reduction of both the read time and read-disturb effects for the RTS data in the in the at-least-one reduced read-frequency zone. Indeed, the first memory cell-reading operation includes applying one reference voltage per memory cell to determine a value of the LSB from a corresponding LSB logical page, one or two reference voltages per memory cell to determine a value of the LMSB from a corresponding LMSB logical page, four or five reference voltages per memory cell to determine a value of the UMSB from a corresponding UMSB logical page, and seven or eight reference voltages per memory cell to determine a value of the MSB from a corresponding MSB logical page.

In addition to the first memory cell-reading operation, the method further includes a second memory cell-reading operation. The second memory cell-reading operation includes reading programmed memory cells in the at-least-one standard read-frequency zone. As set forth above, the lower and upper logical pages of the secondary data, the uncharacterizable data, or the combination thereof require about a same number of read operations in the at-least-one standard read-frequency zone to read. Indeed, the second memory cell-reading operation includes applying three or four reference voltages per memory cell to determine a value of any bit of the LSB, the LMSB, the UMSB, or the MSB respectively from its corresponding LSB logical page, LMSB logical page, UMSB logical page, or MSB logical page.

By way of example, either memory cell-reading operation of the first and second memory cell-reading operations includes—for any single memory cell selected for reading—applying one or more reference voltages to the control gate of the memory cell being read while applying a pass-through voltage Vₚₐₛₛ to each control gate of the control gates of the other memory cells along the same word line. This switches each memory cell of the other memory cells along the same bit line as the memory cell being read to ‘on,’ thereby allowing the threshold voltage Vₜₕ being read to propagate to the dedicated sense amplifier of the bit line for a logical determination of the threshold voltage Vₜₕ against the applied reference voltage V_{ref} (e.g., V_{LSB}). The number of times the foregoing memory cell-reading operation occurs depends upon the bit (e.g., the LSB, the LMSB, UMSB, or the MSB) of the memory cell being read and whether the memory cell being read is in the at-least-one reduced read-frequency zone or the at-least-one standard read-frequency zone. Again, in the instant case of a QLC-based solid-state storage device with a 1-2-4-8 programming scheme in the at-least-one reduced read-frequency zone, the LSB requires only one read operation per memory cell in the at-least-one reduced read-frequency zone to determine its value and the LMSB requires only two read operations per memory cell in the same zone to determine its value. It is for this reason there is reduction in both read time and read-disturb effects for the RTS data in the at-least-one reduced read-frequency zone.

While some particular embodiments have been disclosed herein, and while the particular embodiments have been disclosed in some detail, it is not the intention for the particular embodiments to limit the scope of the concepts provided herein. Additional adaptations and/or modifications can appear to those of ordinary skill in the art, and, in broader aspects, these adaptations and/or modifications are encompassed as well. Accordingly, departures may be made from the particular embodiments disclosed herein without departing from the scope of the concepts provided herein.

What is claimed is:

1. A solid-state storage device configured to reduce read time for read time-sensitive data (“RTS data”), comprising:
one or more flash packages including an array of memory cells;
a controller including:
data-characterizing logic configured to characterize incoming data from a host system as primary data including the RTS data, secondary data including non-RTS data, or uncharacterizable data;
a primary data-programming scheme and a secondary data-programming scheme respectively for at least one reduced read-frequency zone for the primary data and at least one standard read-frequency zone for the secondary data, the uncharacterizable data, or a combination thereof; and
data routing logic configured for routing the primary data to lower logical pages of a plurality of logical pages in the at-least-one reduced read-frequency zone in accordance with a logical-to-physical address translator, the lower logical pages requiring fewer read operations than upper logical pages of the plurality of logical pages to read the primary data; and
one or more busses connecting the one-or-more flash packages to the controller.

2. The solid-state storage device of claim 1, wherein the data-characterizing logic is further configured to characterize the incoming data from the host system as likely to be frequently accessed data or seldomly accessed data, the primary data further including the likely-to-be frequently accessed data and the secondary data further including the likely-to-be seldomly accessed data.

3. The solid-state storage device of claim 1, wherein the primary data-programming scheme and the secondary data-programming scheme are implemented within at least one die of the one-or-more flash packages such that the at-least-one reduced read-frequency zone and the at-least-one standard read-frequency zone are within the at-least-one die.

4. The solid-state storage device of claim 1, wherein the primary data-programming scheme and the secondary data-programming scheme are implemented between at least two different dies of the one-or-more flash packages such that each die of the at-least-two different dies has a different read-frequency zone of the at-least-one reduced read-frequency zone and the at-least-one standard read-frequency zone.

5. The solid-state storage device of claim 1, wherein all blocks of a plurality of blocks in each plane of one or more planes are configured with a same storage capacity.

6. The solid-state storage device of claim 1, wherein each memory cell of the array of memory cells is a triple-level memory cell configured to have an erased state and up to seven programmed states corresponding to a total of eight different amounts of floating gate-trapped electrons with eight different readable threshold voltages for up to three bits of data per memory cell.

7. The solid-state storage device of claim 1, wherein each memory cell of the array of memory cells is a quad-level memory cell configured to have an erased state and up to fifteen programmed states corresponding to a total of sixteen different amounts of floating gate-trapped electrons with sixteen different readable threshold voltages for up to four bits of data per memory cell.

8. The solid-state storage device of claim 7, wherein the primary data-programming scheme is configured for programming the array of memory cells in the at-least-one reduced read-frequency zone such that the primary data is represented by lower significant bits of four-bit tuples in the lower logical pages of four logical pages, the lower significant bits requiring only one or two read operations per memory cell to determine their values.

9. The solid-state storage device of claim 8, wherein the primary data-programming scheme is configured for programming the array of memory cells in the at-least-one reduced read-frequency zone such that the secondary data is represented by upper significant bits of the four-bit tuples in the upper logical pages of the four logical pages, the upper significant bits requiring four to eight read operations per memory cell to determine their values.

10. The solid-state storage device of claim 7, wherein the primary data-programming scheme is configured for programming the array of memory cells in the at-least-one reduced read-frequency zone such that the primary data is represented by a least significant bit (“LSB”), a lower-middle significant bit (“LMSB”), or both the LSB and the LMSB of four-bit tuples, the LSB of a four-bit tuple in an LSB logical page of a set of four logical pages requiring only one read operation per memory cell and the LMSB of a same or different four-bit tuple in an LMSB logical page of the set of four logical pages requiring only one or two read operations per memory cell to determine their values.

11. The solid-state storage device of claim 10, wherein the primary data-programming scheme is configured for programming the array of memory cells in the at-least-one reduced read-frequency zone such that the secondary data is represented by an upper-middle significant bit (“UMSB”), a most significant bit (“MSB”), or both the UMSB and the MSB of the four-bit tuples, the UMSB of the same or different four-bit tuple in a UMSB logical page of the set of four logical pages requiring four or five read operations per memory cell and the MSB of the same or different four-bit tuple in an MSB logical page of the set of four logical pages requiring seven or eight read operations per memory cell to determine their values.

12. The solid-state storage device of claim 11, wherein the secondary data-programming scheme is configured for programming the array of memory cells in the at-least-one standard read-frequency zone such that the secondary data, the uncharacterizable data, or the combination thereof is represented by any combination of the LSB, LMSB, UMSB, or MSB of the four-bit tuples, each bit of the LSB, LMSB, UMSB, or MSB of the same or different four-bit tuple requiring three or four read operations per memory cell to determine its value.

13. The solid-state storage device of claim 1, wherein each memory cell of the array of memory cells is a penta-level memory cell configured to have an erased state and up to thirty-one programmed states corresponding to a total of thirty-two different amounts of floating gate-trapped electrons with thirty-two different readable threshold voltages for up to five bits of data per memory cell.

14. The solid-state storage device of claim 1, the controller further comprising:
a garbage-collection module configured to erase erase-designated blocks of a plurality of blocks including invalid logical pages having invalid data; and
a wear-leveling module configured to evenly distribute valid data from valid logical pages of the erase-designated blocks in a plurality of memory cell-programming instances over erased blocks of the plurality of blocks in each zone of the at-least-one reduced read-frequency zone and the at-least-one standard read-frequency zone in accordance with any recharacterization of the valid data by the data-characterizing logic.

15. A data center configured to reduce read time for read time-sensitive data (“RTS data”), comprising:
a plurality of solid-state storage devices, each solid-state storage device of the plurality of solid-state storage devices including:
an array of memory cells; and
a controller including a processor to handle data flow to and from the array of memory cells;
a primary data-programming scheme and a secondary data-programming scheme respectively for at least one reduced read-frequency zone and at least one standard read-frequency zone, the primary data-programming scheme and the secondary data-programming scheme distributed among different rack-units holding the plurality of solid-state storage devices;
data-characterizing logic configured to characterize incoming data as primary data including the RTS data, secondary data including non-RTS data, or uncharacterizable data; and
data-routing logic configured for routing both the primary data and a portion of the secondary data to the solid-state storage devices in the at-least-one reduced read-frequency zone, lower logical pages including the primary data requiring fewer read operations than upper logical pages including the secondary data.

16. A method implemented by a solid-state storage device configured to reduce read time for read time-sensitive data (“RTS data”), comprising:
characterizing incoming data from a host system as primary data including the RTS data, secondary data including non-RTS data, or uncharacterizable data, the characterizing performed by data-characterizing logic of a controller of the solid-state storage device;
routing the primary data in accordance with a logical-to-physical address translator of the controller to lower logical pages of a plurality of logical pages in at least one reduced read-frequency zone of the solid-state storage device;
programming memory cells with the primary data in the at-least-one reduced read-frequency zone in accordance with a primary data-programming scheme; and
reading programmed memory cells in the at-least-one reduced read-frequency zone, the lower logical pages in the at-least-one reduced read-frequency zone requiring fewer read operations than upper logical pages of the plurality of logical pages in the at-least-one reduced read-frequency zone to read the primary data.

17. The method of claim 16, further comprising:
routing the secondary data to the upper logical pages in the at-least-one reduced read-frequency zone in accordance with the logical-to-physical address translator; and
programming the memory cells in the at-least-one reduced read-frequency zone with the secondary data in accordance with the primary data-programming scheme.

18. The method of claim 17, wherein programming the memory cells in accordance with the primary data-programming scheme includes stepwise programming the memory cells in the at-least-one reduced read-frequency zone such that the primary data is represented by a least significant bit (“LSB”), a lower-middle significant bit (“LMSB”), or both the LSB and the LMSB of four-bit tuples and the secondary data is represented by an upper-middle significant bit (“UMSB”), a most significant bit (“MSB”), or both the UMSB and the MSB of the four-bit tuples, the lower logical pages in the at-least-one reduced read-frequency zone including an LSB logical page and an LMSB logical page and the upper logical pages in the at-least-one reduced read-frequency zone including a UMSB logical page and an MSB logical page.

19. The method of claim 18, wherein reading the programmed memory cells in the at-least-one reduced read-frequency zone includes applying one reference voltage per memory cell to determine a value of the LSB from a corresponding LSB logical page, one or two reference voltages per memory cell to determine a value of the LMSB from a corresponding LMSB logical page, four or five reference voltages per memory cell to determine a value of the UMSB from a corresponding UMSB logical page, and seven or eight reference voltages per memory cell to determine a value of the MSB from a corresponding MSB logical page.

20. The method of claim 16, further comprising:
routing the secondary data, the uncharacterizable data, or a combination thereof in accordance with the logical-to-physical address translator to any combination of lower or upper logical pages of a plurality of logical pages in at least one standard read-frequency zone;
programming the memory cells in the at-least-one standard read-frequency zone in accordance with a secondary data-programming scheme; and
reading programmed memory cells in the at-least-one standard read-frequency zone, the lower and upper logical pages in the at-least-one standard read-frequency zone requiring about a same number of read operations to read the secondary data, the uncharacterizable data, or the combination thereof.
